(19) United States
(12) Patent Application Publication
(10) Pub. No.: US 2002/0130373 A1
(43) Pub. Date: Sep. 19, 2002

(54) Semiconductor device and manufacturing method thereof

(75) Inventors: Shuuichi Ueno, Tokyo (JP); Akinobu Teramoto, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: Mitsubishi Denki Kabushiki Kaisha, Chiyoda-ku (JP)

(21) Appl. No.: 09/928,411

(22) Filed: Aug. 14, 2001

(30) Foreign Application Priority Data
Mar. 14, 2001 (JP) 2001-072129

(51) Int. Cl. H01L 29/76

(52) U.S. Cl. 257/389; 257/411; 257/395

(57) ABSTRACT

A semiconductor device having a MOS transistor capable of effectively reducing leakage current and a method of manufacturing the same are provided. A silicon nitride film (11) is formed at the interface between a silicon substrate (1) and an oxide film (2) in the area except for the region for forming a polysilicon gate electrode (3) (i.e., an out-of-gate-electrode region). A silicon nitride film (13) is formed at the interface between the oxide film (2) and the side surface of the polysilicon gate electrode (3). Since the silicon nitride films (11, 13) can suppress the progress of oxidation, the oxidation of the silicon substrate (1) and the polysilicon gate electrode (3) can be suppressed effectively during a smile oxidation processing for obtaining the final shape of the oxide film (2). This enables to realize the structure that the oxide film (2) on the side surface of the polysilicon gate electrode (3) and the oxide film (2) in the out-of-gate-electrode region are formed so as to be thinner in thickness than the underside of the central portion of the polysilicon gate electrode (3).

### BACKGROUND OF THE INVENTION

1. Field of the Invention

The present invention relates to a semiconductor device and a method of manufacturing the same and, in particular, to a transistor structure of a MOS transistor.

2. Description of the Background Art

As a MOS transistor is scaled, the thickness of an oxide film such as of a gate oxide film is more reduced and a higher field is applied to a (silicon) substrate when the MOS transistor is operated.

Particularly, since the edge of a gate electrode has ideally an angle of 90° or nearly 90°, the field is concentrated to induce high field. Therefore, a region of high field is present in the vicinity of a gate edge portion of a silicon substrate. When a high field is applied into the silicon substrate, due to interband tunneling phenomenon, the hole-electron pairs are generated, which is one of the factors contributing to leakage current. That is, the so-called GIDL (Gate Induced Drain Leakage Current) occurs.

As a method of relaxing a high field in a gate edge proximate region, there is a method of increasing the distance between a gate electrode and a silicon substrate, so that the field concentrated in the vicinity of the gate electrode edge proximity is relaxed before it reaches the silicon substrate.

This relaxing method can be realized easily by increasing the thickness of a gate oxide film. However, the modem trend in gate oxide films is toward miniaturization in thickness, which heretofore have been formed relatively thick. Consider the reason for miniaturization is to supply a large current, the adverse effect of increasing the thickness of a gate oxide film is extremely large and it is thus impractical.

Upon this, a smile oxidation technique has been proposed in order to realize a gate oxide film structure that only the thickness of a gate oxide film beneath the gate edge proximate portion is increased and the thickness of the gate oxide film beneath the gate central proximate portion is decreased.

The smile oxidation technique enables to form a gate oxide film of a gate bird's beak structure that a gate oxide film beneath the gate central proximate portion is made thinner in thickness than the gate oxide film beneath the gate edge proximate portion. The smile oxidation technique is utilized to increase the reliability of the gate oxide film in the proximity of the gate electrode edge.

FIG. 35 is a sectional view illustrating a gate structure before a smile oxidation is performed. As shown in the figure, an oxide film 32 is formed on a silicon substrate 31, and a polysilicon gate electrode 33 is selectively formed on the oxide film 32.

In the etching processing for forming the polysilicon gate electrode 33, immediately after forming the polysilicon gate electrode 33, the region underlying the polysilicon gate electrode 33 is made thicker in thickness than other regions (i.e., an out-of-gate-electrode region).

FIG. 36 is a sectional view illustrating a gate structure after performing the smile oxidation. As shown in the figure, by the smile oxidation, the oxide film 32 grows in the upper part and inner part of the silicon substrate 31 as well as in the side surface and inner part of the polysilicon gate electrode 33. Thereby the area except for the region underlying the polysilicon gate electrode 33 is made thicker in thickness than that region.

At this time, since the polysilicon gate electrode 33 has a higher degree of oxidation than the silicon substrate 31, the erosion (retreat) amount in the polysilicon gate electrode 33 due to the oxide film 32 is larger than that in the silicon substrate 31.

The reason for this is that the (1,1, 1)-oriented plane of silicon is less susceptible to oxidation than other planes. That is, the silicon substrate 31 is a single crystal and its surface exposed to an oxidation atmosphere is formed by the (1,1,1)-oriented plane. On the other hand, since polysilicon is of a grain group, its various planes are exposed to an oxidation atmosphere and the oxidation is facilitated than the silicon substrate. Besides, the enhanced oxidation due to the impurities contained in the polysilicon gate electrode 33 contributes markedly to the erosion amount in the polysilicon gate electrode 33.

Conventionally, for the purpose of reducing the leakage current due to GIDL, a smile oxidation is performed after forming a gate electrode, thereby to relax the field in the proximity of a gate edge portion. Thereby, the oxide film of the gate edge portion is formed thickly in thickness so as to obtain a gate bird's beak structure.

However, a gate electrode and a silicon substrate are also subjected to oxidation when the smile oxidation for obtaining a gate bird's beak structure is carried out in an atmosphere to facilitate oxidation, or at high temperatures, or for a long time.

When the gate electrode is oxidized, the distance (forming length) of the gate electrode being electrically conductor is reduced, therefore, the oxidation of the gate electrode is not assumed. In the case of forming a MOS transistor to which a drain structure estimating the oxidation amount of the gate electrode at a low value is applied, the inevitable result is to form an offset region at which a gate field is hard to propagate to a channel. Since the offset region cannot capture electrons, there is the problem that the resistance value rapidly increases and the amount of current flowing the channel decreases.

In LSIs, a large number of transistors are generally formed in a chip. Therefore, even if every transistor employs the drain structure to avoid the formation of an offset region, there remains a small chance of manufacturing a MOS transistor in which due to abnormal diffusion or the like, oxidation is proceeded in part of the gate electrode, thereby causing an offset region. Hence, it is an assumption of sufficiently practical level to consider the possibility of manufacturing a MOS transistor employing such a drain structure that is unsuitable if the gate electrode is oxidized.

In the structures having the same gate length and the optimized drain structure to avoid offset, when an element wherein polysilicon as a gate electrode material is oxidized is compared with an element wherein polysilicon is not oxidized, the effective (which means to be capable of handing as a conductor) gate length, namely channel length, of the former is shorter than that of the latter.

Accordingly, when the miniaturization of the gate length is proceeded, the former reaches its limit earlier than the latter. Therefore, it can be considered that the latter is more suitable for miniaturization than the former.

By performing a smile oxidation, the interface of a silicon substrate in the direction from a gate edge to a drain region is expanded by oxidation. The process of oxidation of silicon is the process that silicon and oxygen form a compound. It is necessary that silicon and the elements of an oxide film enter the space formed only by silicon. Thus a large stress is induced in the region where much silicon is oxidized. Of course, such stress is partly relaxed by spatial expansion. However, the stress is apparently increased after forming an oxide film by the smile oxidation technique, than the stress before oxidation. When stress is induced in the silicon substrate, the band gap of silicon is changed and, in some instances, the leakage current is increased. Further, when the stress becomes greater than the binding energy between atoms, the atoms break the bond to shift their positions in order to relax the stress. This case also causes a defect and the leakage current is increased.

Thus, it is harmful effects on the transistor performance that the gate electrode and silicon substrate are oxidized by the smile oxidation processing. Hence, there is the problem that the thickness and forming length of a gate bird's beak which can be formed by the smile oxidation processing are subjected to rate-determining depending on the oxidation amount of polysilicon and the oxidation amount of the silicon substrate.

### SUMMARY OF THE INVENTION

According to a first aspect of the invention, a semiconductor device includes a MOS transistor having a semiconductor substrate, an oxide film disposed on the semiconductor substrate, and a gate electrode selectively disposed on the oxide film, the oxide film being disposed on an underside and a side surface of the gate electrode, and being disposed on the semiconductor substrate in an out-of-gate-electrode region corresponding to a region other than the underside, side surface and other regions of the gate electrode, the oxide film underling the gate electrode being made thicker in thickness under the edge proximity than under the central portion of the gate electrode, and the oxide film to be disposed on the out-of-gate-electrode region being made thinner in thickness than the oxide film to be disposed on the side surface of the gate electrode.

According to a second aspect of the invention, the semiconductor device of the first aspect is characterized in that the oxide film to be disposed on the out-of-gate-electrode region is made thinner in thickness than the oxide film under the central portion of the gate electrode.

According to a third aspect of the invention, the semiconductor device of the first aspect further comprises an oxidation inhibiting layer composed of an antioxidant disposed between the semiconductor substrate and the oxide film in the out-of-gate-electrode region.

According to a fourth aspect of the invention, a semiconductor device includes a MOS transistor having a semiconductor substrate, an oxide film disposed on the semiconductor substrate and a gate electrode selectively disposed on the oxide film, the oxide film being disposed on an underside and a side surface of the gate electrode, the oxide film underling the gate electrode being made thicker in thickness under the edge proximity than under the central portion of the gate electrode, and the oxide film to be disposed on the side surface of the gate electrode being made thinner than the oxide film to be disposed under the central portion of the gate electrode.

According to a fifth aspect of the invention, the semiconductor device of the fourth aspect further comprises an oxidation inhibiting layer composed of an antioxidant disposed between the side surface of the gate electrode and the oxide film.

According to a sixth aspect of the invention, the semiconductor device of the fourth aspect is characterized in that the oxide film is also disposed on the semiconductor substrate in an out-of-gate-electrode region corresponding to a region other than the underside and side surface of the gate electrode; and that the oxide film in the out-of-gate-electrode region is made thinner in thickness than the oxide film to be disposed under the central portion of the gate electrode.

According to a seventh aspect of the invention, the semiconductor device of the sixth aspect further comprises: a first oxidation inhibiting layer composed of an antioxidant disposed between the side surface of the gate electrode and the oxide film; and a second oxidation inhibiting layer composed of an antioxidant disposed between the semiconductor substrate and the oxide film in the out-of-gate-electrode region.

According to an eighth aspect of the invention, a method of manufacturing a semiconductor device comprises the steps of: (a) successively depositing an oxide film and a conductive layer on a semiconductor substrate; (b) patterning the conductive layer to form a gate electrode, by performing the step (b), the oxide film being made thinner in thickness in an out-of-gate electrode region where the gate electrode is not formed; (c) forming an oxidation inhibiting layer composed of an antioxidant between the oxide film and the semiconductor substrate in the out-of-gate-electrode region; (d) performing an oxidation processing over the entire surface of the semiconductor substrate after the step (c); and (e) introducing impurity of a predetermined conductivity by using the gate electrode as a mask, to form a source/drain region in the surface of the semiconductor substrate, wherein a MOS transistor is made up of the gate electrode, the oxide film underlying the gate electrode and the source/drain region, by performing the step (d), the oxide film underlying the gate electrode is formed on the side surface of the gate electrode and is made thicker in thickness under the edge proximity than the under the central portion of the gate electrode, and the oxide film in the out-of-gate-electrode region is made thinner in thickness than the oxide film to be disposed on the side surface of the gate electrode.

According to a ninth aspect of the invention, the method of the eighth aspect is characterized in that by performing the step (d), the oxide film in the out-of-gate-electrode region is made thinner in thickness than the oxide film underlying the central portion of the gate electrode.

According to a tenth aspect of the invention, the method of the eighth aspect is characterized in that the step (c) includes the step of implanting from above gas having an oxidation inhibiting function and having higher reactivity with the semiconductor substrate than the oxide film by using the gate electrode as a mask, to form the oxidation inhibiting layer.

According to an eleventh aspect of the invention, a method of manufacturing a semiconductor device comprises the steps of: (a) successively depositing an oxide film and a conductive layer on a semiconductor substrate; (b) patterning the conductive layer to form a gate electrode; (c) forming a first oxidation inhibiting layer composed of an antioxidant on the side surface of the gate electrode; (d) performing, an oxidation processing over the entire surface of the semiconductor substrate after the step (c); and (e) introducing impurity of a predetermined conductivity by using the gate electrode as a mask, to form a source/drain region in the surface of the semiconductor substrate, wherein a MOS transistor is made up of the gate electrode, the oxide film underlying the gate electrode and the source/drain region, by performing the step (d), the oxide film underlying the gate electrode is formed on the side surface of the gate electrode and is made thicker in thickness under the edge proximity than under the central portion of the gate electrode, and the oxide film to be disposed on the side surface of the gate electrode is made thinner in thickness than the oxide film underlying the central portion of the gate electrode.

According to a twelfth aspect of the invention, the method of the eleventh aspect is characterized in that the step (b) includes the step of allowing part of the conductive layer to remain in an out-of-gate-electrode region corresponding to the area except for the region for forming the gate electrode, and that the step (c) further includes the step of removing the conductive layer and the first oxidation inhibiting layer in the out-of-gate-electrode region after forming the first oxidation inhibiting layer.

According to a thirteenth aspect of the invention, the method of the twelfth aspect is characterized in that the step (c) includes a thermal treatment, and that the step (e) includes the steps of: (e-1) introducing impurity of the predetermined conductivity at a first impurity concentration; and (e-2) introducing impurity of the predetermined conductivity at a second impurity concentration higher than the first impurity concentration, and that the step (e-1) is performed before the step (c).

According to a fourteenth aspect of the invention, the method of the twelfth aspect is characterized in that the step (e) includes the steps of: (e-1) introducing impurity of the predetermined conductivity at a first impurity concentration; and (e-2) introducing impurity of the predetermined conductivity at a second impurity concentration higher than the first impurity concentration, and that the step (e-1) is performed after the step (d).

According to a fifteenth aspect of the invention, the method of the eleventh aspect is characterized in that the step (c) includes the step of supplying gas having an oxidation inhibiting function and reacting with the conductive layer including the gate electrode.

According to a sixteenth aspect of the invention, the method of the eleventh aspect is characterized in that by performing the step (b), the oxide film is made thinner in thickness in an out-of-gate-electrode region where the gate electrode is not formed, that the step (c) includes the step of forming a second oxidation inhibiting layer composed of an antioxidant between the oxide and the semiconductor substrate film in the out-of-gate-electrode region, and that by performing the step (d), the oxide film in the out-of-gate-electrode region is made thinner in thickness than the oxide film to be disposed under the central portion of the gate electrode.

According to a seventeenth aspect of the invention, the method of the sixteenth aspect is characterized in that the step (c) includes the step of supplying gas having an oxidation inhibiting function, reacting with the gate electrode and having higher reactivity with the semiconductor substrate than the oxide film.

In the semiconductor device of the first aspect, the oxide film in the out-of-gate-electrode region is formed so thinly in thickness to realize the structure that the oxide film has little curved portions even below the edge proximity of the gate electrode. This enables to relax the concentration of field when the MOS transistor is operated and also reduce the stress on the silicon substrate during oxidation processing, thus attaining a reduction in leakage current.

In the semiconductor device of the second aspect, a reduction in leakage current is attainable by forming the oxide film in the out-of-gate-electrode region so as to be thinner in thickness than the oxide film underlying the central portion of the gate electrode.

In the semiconductor device of the third aspect, the presence of the oxidation inhibiting layer effectively suppresses the surface of the semiconductor substrate in the out-of-gate-electrode region from being oxidized during oxidation processing. Therefore, the oxide film in the out-of-gate-electrode region can be formed so as to be thinner in thickness than the oxide film disposed on the side surface of the gate electrode or the oxide film underlying the central portion of the gate electrode by performing one oxidation processing.

In the semiconductor device of the fourth aspect, a reduction in the supply current amount of the MOS transistor can be suppressed effectively by forming the oxide film disposed on the side surface of the gate electrode so as to be thinner in thickness than the oxide film disposed below the central portion of the gate electrode.

In the semiconductor device of the fifth aspect, the presence of the oxidation inhibiting layer effectively suppresses the side surface of the gate electrode from being oxidized during oxidation processing. Therefore, the oxide film disposed on the side surface of the gate electrode can be formed so as to be thinner in thickness than the oxide film underlying the central portion of the gate electrode by performing one oxidation processing.

In the semiconductor device of the sixth aspect, a further reduction in leakage current is attainable by forming the oxide film in the out-of-gate-electrode region so as to be thinner in thickness than the oxide film underlying the central portion of the gate electrode.

In the semiconductor device of the seventh aspect, the presence of the first and second oxidation inhibiting layers effectively suppress the side surface of the gate electrode and the semiconductor substrate in the out-of-gate-electrode region from being oxidized during oxidation processing, respectively. Therefore, the oxide film disposed on the side surface of the gate electrode and the oxide film in the out-of-gate-electrode region can be formed so as to be thinner in thickness than the oxide film underlying the central portion of the gate electrode by performing one oxidation processing.

In the manufacturing method of the eighth aspect, the presence of the oxidation inhibiting layer formed in the step (c) effectively suppresses the surface of the semiconductor substrate in the out-of-gate-electrode region from being oxidized during oxidation processing of the step (d). Therefore, the oxide film in the out-of-gate-electrode can be formed reliably so as to be thinner in thickness than the oxide film to be disposed on the side surface of the gate electrode by performing one oxidation processing.

Thereby, it is able to obtain the oxide film having the structure of hardly causing curved portions even below the edge proximity of the gate electrode. This enables to relax the concentration of field when the MOS transistor is operated and also reduce the stress on the semiconductor substrate during oxidation processing, thus attaining a reduction in leakage current.

In the MOS transistor manufactured by the method of the ninth aspect, a reduction in leakage current is attainable by forming the oxide film in the out-of-gate-electrode region so as to be thinner in thickness than the oxide film underlying the central portion of the gate electrode.

In the manufacturing method of the tenth aspect, the oxidation inhibiting layer can be formed reliably between the oxide film in the out-of-gate-electrode region and the semiconductor substrate, by implanting from above gas having oxidation inhibiting function and having higher reactivity with the semiconductor substrate than the oxide film.

In the manufacturing method of the eleventh aspect, the presence of the first oxidation inhibiting layer formed in the step (c) effectively suppresses the side surface of the gate electrode from being oxidized during oxidation processing of the step (d). Therefore, the oxide film formed on the side surface of the gate electrode can be formed reliably so as to be thinner in thickness than the oxide film underlying the central portion of the gate electrode. As a result, a reduction in the supply current amount of the MOS transistor can be suppressed effectively.

In the manufacturing method of the twelfth aspect, by allowing part of the conductive layer to remain in the out-of-gate-electrode region in the step (b), it can be reliably avoided that an oxidation inhibiting layer is formed between the oxide film and the semiconductor substrate in the out-of-gate-electrode region when performing the step (c).

In the manufacturing method of the thirteenth aspect, by performing the step (e-1) that is part of the impurity implantation processing for forming a source/drain region prior to the oxidation inhibiting layer forming processing in the step (c), the diffusion phenomenon in the thermal treatment of the step (c) is utilized to obtain a gentle impurity profile of the source/drain region, thereby attaining a reduction in leakage current.

In the manufacturing method of the fourteenth aspect, the step (e-1) that is part of the impurity implantation processing for forming a source/drain region is carried out after the oxidation processing of the step (d). Therefore, by introducing impurity through the oxide film of which thickness is increased than that before the step (d), part of the source/drain region can be formed in a relatively shallow region.

In the manufacturing method of the fifteenth aspect, by supplying gas having oxidation inhibiting function and reacting with the conductive layer including the gate electrode in the step (c), the first oxidation inhibiting layer can be formed reliably on the side surface of the gate electrode.

In the manufacturing method of the sixteenth aspect, the presence of the second oxidation inhibiting layer formed in the step (c) effectively suppresses the semiconductor substrate in the out-of-gate-electrode region from being oxidized during the oxidation processing of the step (d). Therefore, the oxide film in the out-of-gate-electrode region can be formed reliably so as to be thinner in thickness than the oxide film underlying the central portion of the gate electrode, thus attaining a reduction in leakage current.

In the manufacturing method of the seventeenth aspect, by supplying, in the step (c), gas having oxidation inhibiting function, reacting with the gate electrode and having higher reactivity with the semiconductor substrate than the oxide film, the first oxidation inhibiting layer can be formed reliably on the side surface of the gate electrode, and the second oxidation inhibiting layer can be formed reliably between the oxide film and the semiconductor substrate in the out-of-gate-electrode region.

It is an object of the present invention to overcome the foregoing problem by providing a semiconductor device having a MOS transistor capable of effectively reducing leakage current, as well as a method of manufacturing the same.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view illustrating a silicon nitride film forming processing;

FIG. 2 is a sectional view illustrating a smile oxidation processing to the structure of FIG. 1;

FIG. 3 is a sectional view illustrating the gate edge surroundings of a polysilicon gate electrode before smile oxidation;

FIG. 4 is a sectional view illustrating the gate edge surroundings after smile oxidation;

FIG. 5 is a sectional view illustrating the gate electrode edge proximate region in a MOS transistor that is the principle of a first preferred embodiment of the invention;

FIG. 6 is a sectional view illustrating the gate electrode edge proximate region in a real MOS transistor of the first preferred embodiment;

FIG. 7 is a sectional view illustrating the gate electrode edge proximate region in a MOS transistor that is the principle of a second preferred embodiment of the invention;

FIG. 8 is a sectional view illustrating the gate electrode edge proximate region in a real MOS transistor of the second preferred embodiment;

FIG. 9 is a sectional view illustrating the gate electrode edge proximate region in a MOS transistor that is the principle of a third preferred embodiment of the invention;

FIG. 10 is a sectional view illustrating the gate electrode edge proximate region in a real MOS transistor of the third preferred embodiment;

FIGS. 11 to 18 are sectional views illustrating in sequence the steps in a method of manufacturing a MOS transistor according to a fourth preferred embodiment;

FIG. 19 is a sectional view illustrating the step of forming a silicon nitride film in a method of manufacturing a MOS transistor according to a fifth preferred embodiment;

FIG. 20 is a sectional view illustrating the step of forming a silicon nitride film in a method of manufacturing a MOS transistor according to a sixth preferred embodiment;

FIGS. 21 to 26 are sectional views illustrating in sequence the steps in a method of manufacturing a MOS transistor according to a seventh preferred embodiment;

FIGS. 27 to 30 are sectional views illustrating in sequence the steps in a method of manufacturing a MOS transistor according to an eighth preferred embodiment;

FIGS. 31 to 33 are sectional views illustrating in sequence the steps in a method of manufacturing a MOS transistor according to a ninth preferred embodiment;

FIG. 34 is a sectional view illustrating the step of forming a silicon nitride film in a method of manufacturing a MOS transistor according to a tenth preferred embodiment;

FIG. 35 is a sectional view illustrating a gate structure before smile oxidation processing; and

FIG. 36 is a sectional view illustrating a gate structure after smile oxidation processing.

### DESCRIPTION OF THE PREFERRED EMBODIMENTS

<Technique of Premise>

Silicon Nitride Film

To avoid that a gate electrode composed of polysilicon and a silicon substrate are oxidized during a smile oxidation proessing, it can be considered to use a nitrogen compound as an antioxidant. It is generally known that nitrogen does not transmit oxygen. Also, there is the fact that nitrogen is utilized as an oxidation inhibiting film.

When a nitrogen compound is formed so as to cover the entire surface of an element forming region and then a smile oxidation processing is performed, no antioxidant is introduced into the element. As a result, although the gate electrode and silicon substrate are not oxidized, no gate bird's beak structure is obtained, which is pointless result. That is, it is essential that an antioxidant be ideally supplied only to the gate electrode edge proximity.

FIG. 1 is a sectional view illustrating a silicon nitride film forming processing. FIG. 1 premises the structure that an oxide film 2 is formed on a silicon substrate 1 and a polysilicon gate electrode 3 is selectively formed on the oxide film 2.

Referring to FIG. 1, an NO gas 10 is introduced from the side surface of the polysilicon gate electrode 3 and it undergoes reactions on the side surface of the polysilicon gate electrode 3 and a silicon nitride film 13 can be formed thereon.

On the other hand, in the case that an NO gas 10 is introduced from above the part of the oxide film 2 at which the polysilicon gate electrode 3 is not formed, the NO gas 10 can pass through the oxide film 2 and a silicon nitride film 11 can be formed on the surface of the silicon substrate 1. This is because when the reactant of nitrogen and silicon is compared to the reactant of nitrogen and a silicon oxide film, the former is more stable, that is, nitrogen has a higher reactivity with the silicon substrate than the silicon oxide film.

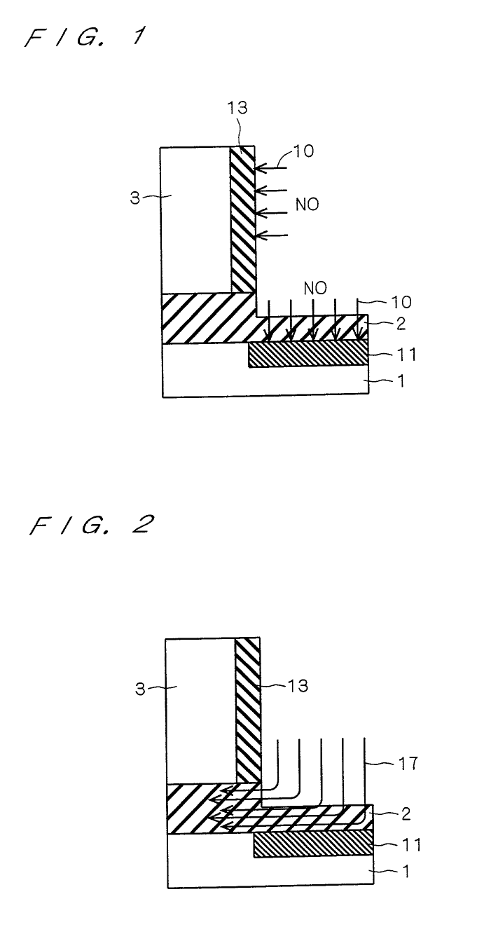

FIG. 2 is a sectional view illustrating the state that a smile oxidation is performed to the structure of FIG. 1. Referring to FIG. 2, by virtue of the oxidation inhibiting function of the silicon nitride films 11 and 13, an oxidant 17 reaches neither the surface of the silicon substrate 1 nor the side surface of the polysilicon gate electrode 3.

Accordingly, the oxidation of the silicon substrate 1 and polysilicon gate electrode 3 can be suppressed effectively, while a gate bird's beak is formed by allowing the oxide film 2 to grow by a smile oxidation processing.

Smile Oxidation

A smile oxidation processing enables to minimize the field within the silicon substrate in the gate edge proximity because of the following first and second factors.

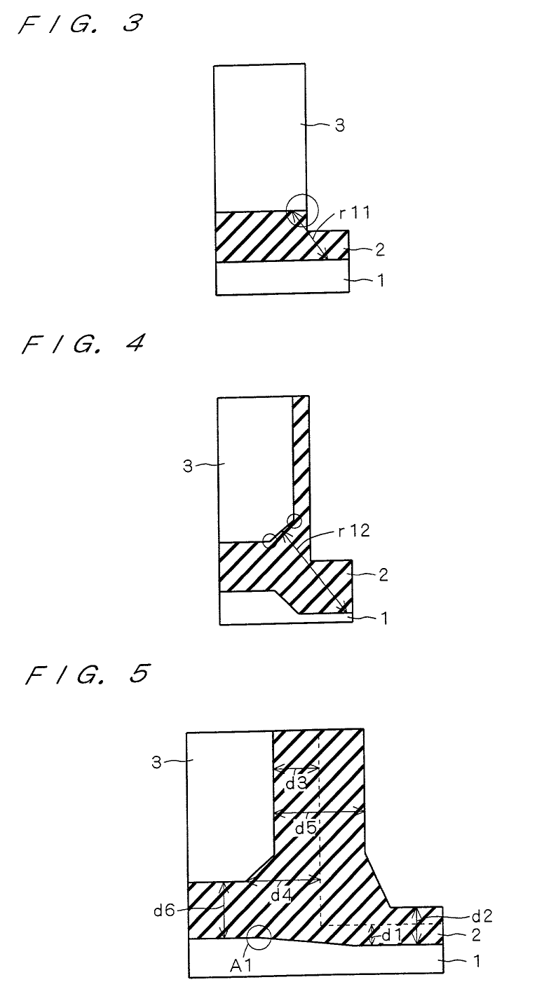

FIG. 3 is a sectional view illustrating the gate edge surroundings of the polysilicon gate electrode 3 before smile oxidation. FIG. 4 is a sectional view illustrating the gate edge surroundings of the polysilicon gate electrode 3 after smile oxidation.

Before smile oxidation, the corners of the polysilicon gate electrode 3 have an angle of 90° as shown in FIG. 3. After smile oxidation, the lower edges of the polysilicon gate electrode 3 are rounded as shown in FIG. 4. Specifically, by rounding field sources (the areas indicated by circle in FIGS. 3 and 4), the concentration of field is avoidable and a reduction of field is attainable. This is the first factor.

As apparent from a comparison of FIG. 3 with FIG. 4, the thickness of the oxide film 2 after smile oxidation is larger than that before smile oxidation, thereby elongating field propagation paths indicated by arrow in FIGS. 3 and 4. That is, since a high field generated at the edge beneath the polysilicon gate electrode 3 is hard to reach the silicon substrate 1, the field observed in the silicon substrate 1 can be minimized. This is the second factor.

However, there is the drawback that the smile oxidation involves the oxidation of the gate electrode 3 and silicon substrate 1 as stated above.

Consequently, part of the present invention aims that even with a smile oxidation processing, an oxide film is hardly formed on the silicon substrate 1. This means that it is able to perform a smile oxidation without inducing any stress in the silicon substrate 1. As previously described, there is the possibility that when stress is induced in the silicon substrate 1, leakage current is increased. Therefore, the effect of preventing an increase in leakage current can be expected by preventing the silicon substrate 1 from being oxidized during smile oxidation.

Omission of Selective Oxidation

In existing LSIs, usually a gate electrode is directly utilized as wiring. If considered as wiring, the gate electrode is highly required to be of low resistance. However, polysilicon to which impurity widely used as a gate electrode material is introduced has a higher resistance than a metal wiring such as of aluminum. For this, the technique of forming a gate electrode by two layers or multi-layer of polysilicon and a film made of metal is generally used.

However, a metal film has a tendency to be more susceptible to oxidation than a polysilicon film. By smile oxidation, the metal film is more oxidized than the polysilicon film. As a result, the forming width of the metal film subjected to more oxidation is shortened to increase the resistance value. This leads to the problem that the inherent function of reducing the resistance in forming a metal film cannot be executed in some instances.

As a technique of solving the above problem, there is for example selective oxidation. The selective oxidation technique is a technique of incorporating an oxidation gas and a reducing agent (e.g., hydrogen) at the same time. Thereby, the oxidized metal surface can be reduced to return to its normal state and the degree of oxidation of the metal can be lowered.

It should be noted that an expensive apparatus of high safety is necessary because an explosive gas such as a mixed gas of hydrogen and oxygen is handled in performing selective oxidation. This leads to an increase in the manufacturing cost.

Thus, if considered the manufacturing cost, it is necessary to obtain a gate bird's beak structure by a single smile oxidation processing, without employing the selective oxidation technique.

First Preferred Embodiment

First Characteristic Feature

FIG. 5 is a sectional view illustrating the gate electrode edge proximate region in a MOS transistor that is the principle of a first preferred embodiment of the invention. Referring to FIG. 5, an oxide film 2 is formed on a silicon substrate 1, and a polysilicon gate electrode 3 is selectively formed on the oxide film 2. The oxide film 2 underlying the polysilicon gate electrode 3 becomes a gate oxide film.

The oxide film 2 has a bird's beak shape that the oxide film 2 underlying the polysilicon gate electrode 3 is made thicker in thickness under the edge proximity than the central portion, by a smile oxidation to be performed after patterning the polysilicon gate electrode 3.

In FIG. 5, a substrate erosion amount d1 indicates the oxidized amount of the silicon substrate 1 during smile oxidation, namely, a distance from the lower interface of the oxide film 2 before smile oxidation (indicated by a broken line) to the lower interface of the oxide film 2 after smile oxidation.

On-substrate thickness d2 indicates a thickness of the oxide film 2 on the silicon substrate 1 after smile oxidation. Gate erosion amount d3 indicates a distance from the side surface of the polysilicon gate electrode 3 before smile oxidation to the side surface of the polysilicon gate electrode 3 after smile oxidation. Gate edge erosion amount d4 indicates a distance from the lower edge of the polysilicon gate electrode 3 before smile oxidation to the lower edge of the polysilicon gate electrode 3 after smile oxidation.

Gate sidesurface thickness d5 indicates a thickness of the oxide film 2 on the side surface of the polysilicon gate electrode 3 after smile oxidation. Under-gate-electrode thickness d6 indicates a thickness of the oxide film 2 under the central portion of the polysilicon gate electrode 3 except for the lower edge proximate region of the polysilicon gate electrode 3.

The first characteristic feature of the structure of the first preferred embodiment is that the on-substrate thickness d2 of the oxide film 2 is smaller than the gate sidesurface thickness d5. By forming the oxide film 2 so as to have a small gate sidesurface thickness d5, a surface region A1 of the silicon substrate 1, which is located immediately below the gate edge, has little curved portions. This enables to relax the concentration of field when the MOS transistor is operated, and also considerably reduce the stress on the silicon substrate 1 during oxidation processing.

Thus, thanks to the first characteristic feature of the first preferred embodiment, a reduction in leakage current is attainable by relaxing the field concentration and reducing the stress as described above. Therefore, improvements in retention characteristic can be expected than the case of performing the usual smile oxidation.

Second Characteristic Feature

The second characteristic feature of the first preferred embodiment is that the on-substrate thickness d2 is smaller than the under-gate-electrode thickness d6. Its resulting effect is the same as that of the first characteristic feature.

Outline of Manufacturing Method

The structure as set forth in the first preferred embodiment can be manufactured in the following manner, which will roughly be described as below.

When a polysilicon layer is etched for patterning a polysilicon gate electrode 3, it is unavoidable that an oxide film 2 is used as an etching stopper. Therefore, the oxide film 2 located in the area except for the region for forming the polysilicon gate electrode 3 (hereinafter referred to simply as an “out-of-gate-electrode region” in some cases) is exposed to an etching atmosphere. As a result, the thickness of the oxide film 2 in the out-of-gate-electrode region immediately after patterning the polysilicon gate electrode 3, is smaller than the thickness of the oxide film 2 underlying the central portion of the polysilicon gate electrode 3 (see FIG. 35).

By the following smile oxidation processing, the oxide film 2 in the out-of-gate-electrode region is exposed to an oxidation atmosphere, thereby to increase its thickness. Even in the oxidation atmosphere, by performing an oxidation suppression (prevention) processing to suppress the progress of oxidation, the structure of the first preferred embodiment is realized.

Practical Structure

FIG. 6 is a sectional view illustrating the gate electrode edge proximate region in a practical MOS transistor according to the first preferred embodiment.

Referring to FIG. 6, a silicon nitride film 11 is formed at the interface between a silicon substrate 1 and an oxide film 2 in the out-of-gate-electrode region. The silicon nitride film 11 functions as an oxidation inhibiting layer that can inhibit the enter of oxygen and suppress the progress of oxidation.

Thus, by forming the silicon nitride film 11 at the interface between the silicon substrate 1 and oxide film 2, the oxidation of the surface of the silicon substrate 1 in the out-of-gate-electrode region during smile oxidation processing can be suppressed effectively. Note that in place of the silicon nitride film 11, an oxidation inhibiting layer may be formed by using other material having the function of inhibiting oxidation.

Second Preferred Embodiment

Principle

FIG. 7 is a sectional view illustrating the gate electrode edge proximate region in a MOS transistor that is the principle of a second preferred embodiment of the invention. Referring to FIG. 7, by a smile oxidation to be performed after patterning a polysilicon gate electrode 3, an oxide film 2 has a bird's beak shape that the oxide film 2 underlying the polysilicon gate electrode 3 is made thicker in thickness under the edge proximity than the under-gate-electrode thickness d6.

Further, the gate sidesurface thickness d5 is made smaller than the under-gate-electrode thickness d6. A small gate sidesurface thickness d5 permits a reduction in the gate erosion amount d3.

When the MOS transistors of the same drain structure are compared, since the structure of the second preferred embodiment has a smaller gate erosion amount d3, the polysilicon gate electrode 3 can more effectively suppress a reduction in the supply current amount of the MOS transistor due to the formation of an offset region against the drain edge.

Assuming the case that the gate erosion amount d3 is large, in order to prevent the formation of an offset region, it can be considered to take such a measure that the drain region is formed so as to be recessed from the gate edge to the central portion of the channel region.

However, if this measure is taken, the effective channel length is shortened. Therefore, this measure is impractical in MOS transistors with the aim of miniaturization.

Thus, the structure of the second preferred embodiment can exhibit excellent electric characteristic in the miniaturized MOS transistors.

Practical Structure

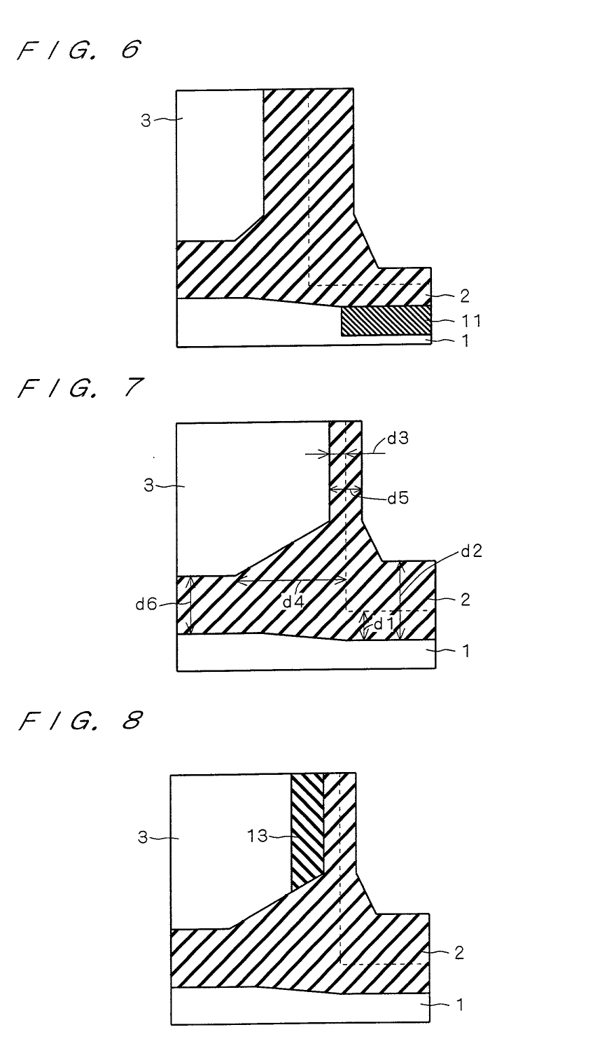

FIG. 8 is a sectional view illustrating the gate electrode edge proximate region in a practical MOS transistor according to the second preferred embodiment. Referring to FIG. 8, a silicon nitride film 13 is formed at the interface between an oxide film 2 and the side surface of a polysilicon gate electrode 3.

The silicon nitride film 13 functions as an oxidation inhibiting layer that reduces the entry of oxygen and suppress the progress of oxidation. By forming the silicon nitride film 13 at the interface between the side surface of the polysilicon gate electrode 3 and the oxide film 2, the oxidation of the side surface of the polysilicon gate electrode 3 during smile oxidation processing can be suppressed effectively. In place of the silicon nitride film 13, an oxidation inhibiting layer may be formed by using other material having the function of inhibiting oxidation.

Third Preferred Embodiment

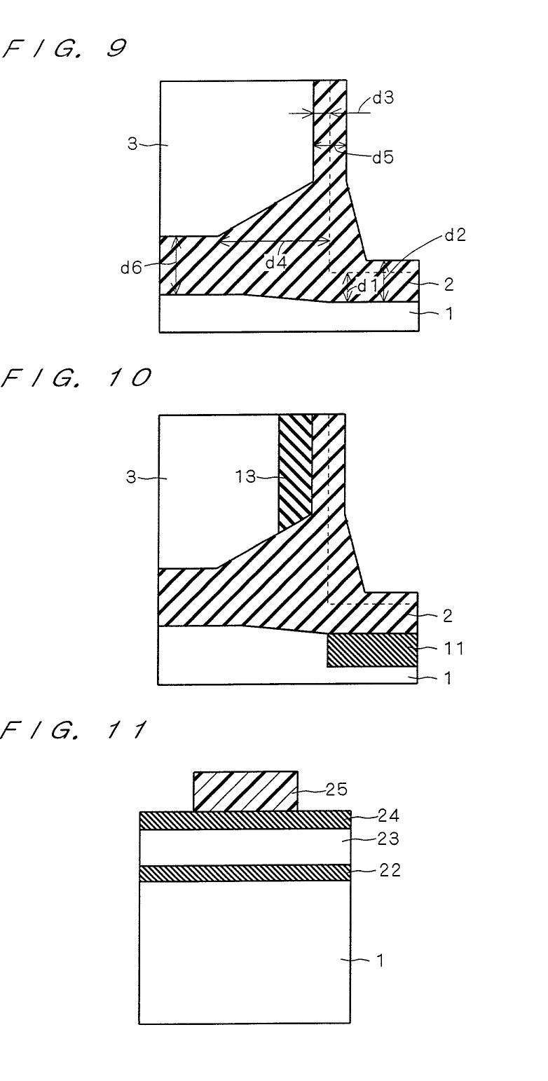

FIG. 9 is a sectional view illustrating the gate electrode edge proximate region in a MOS transistor that is the principle of a third preferred embodiment of the invention. Referring to FIG. 9, by a smile oxidation to be performed after patterning a polysilicon gate electrode 3, an oxide film 2 has a bird's beak shape that the oxide film 2 underlying the polysilicon gate electrode 3 is made thicker in thickness under the edge proximity than under the central portion.

Like the second characteristic feature of the first preferred embodiment, the on-substrate thickness d2 is smaller than the under-gate-electrode thickness d6. Also, like the second preferred embodiment, the gate sidesurface thickness d5 is smaller than the under-gate-electrode thickness d6.

Accordingly, the leakage current reducing effect is attained like the second characteristic feature of the first preferred embodiment, and a reduction in the supply current amount of the MOS transistor can be suppressed effectively, like the effect of the second preferred embodiment.

FIG. 10 is a sectional view illustrating the gate electrode edge proximate region in a practical MOS transistor according to the third preferred embodiment. Referring to FIG. 10, a silicon nitride film 11 is formed at the interface between a silicon substrate 1 and an oxide film 2 in the out-of-gate-electrode region, and a silicon nitride film 13 is formed at the interface between the oxide film 2 and the side surface of a polysilicon gate electrode 3.

Since the silicon nitride films 11 and 13 can suppress the progress of oxidation, the oxidation of the surface of the silicon substrate 1 and of the side surface of the polysilicon gate electrode 3 in the out-of-gate-electrode region during smile oxidation processing can be suppressed effectively. In place of the silicon nitride films 11 and 13, oxidation inhibiting layers using other material having the function of inhibiting oxidation may be formed respectively.

Fourth Preferred Embodiment

FIGS. 11 to 18 are sectional views illustrating in sequence the steps in a method of manufacturing a MOS transistor according to a fourth preferred embodiment. The manufacturing method of this embodiment is a method for obtaining the structure of the third preferred embodiment shown in FIG. 10.

Referring now to FIG. 11, after an element isolation region, a well region and a channel dope layer (all of which are not shown) are formed on a silicon substrate 1, an oxide film 22, a polysilicon layer 23 and an etching mask oxide film 24 are successively deposited. For instance, the oxide film 22, polysilicon layer 23 and etching mask oxide film 24 are formed in a thickness of 8.0 nm, 200.0 nm and 100.0 nm, respectively.

A resist 25 is applied thereto, followed by photolithography step. The resist 25 is then patterned such that the region corresponding to a polysilicon gate electrode is left.

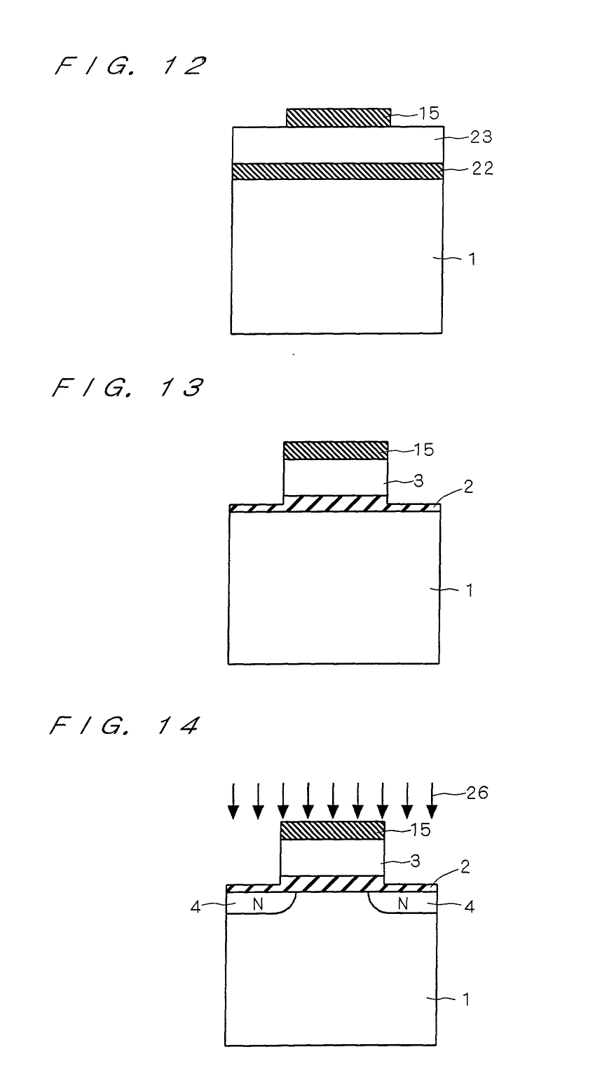

Referring to FIG. 12, by using the resist 25 as a mask, the etching mask oxide film 24 is etched to form a mask oxide film pattern 15 for forming the polysilicon gate electrode.

Referring to FIG. 13, by using the mask oxide film pattern 15 as a mask, the polysilicon layer 23 is etched (patterned) to form a polysilicon gate electrode 3 and an oxide film 2.

At this time, the etching is stopped at the oxide film 22. On the other hand, part of the oxide film 22 in the out-of-gate-electrode region is etched away, resulting in an oxide film 2 having a small thickness in thickness in the out-of-gate-electrode region. For instance, the thickness of the oxide film 2 in the out-of-gate-electrode region is reduced to about 5.0 nm.

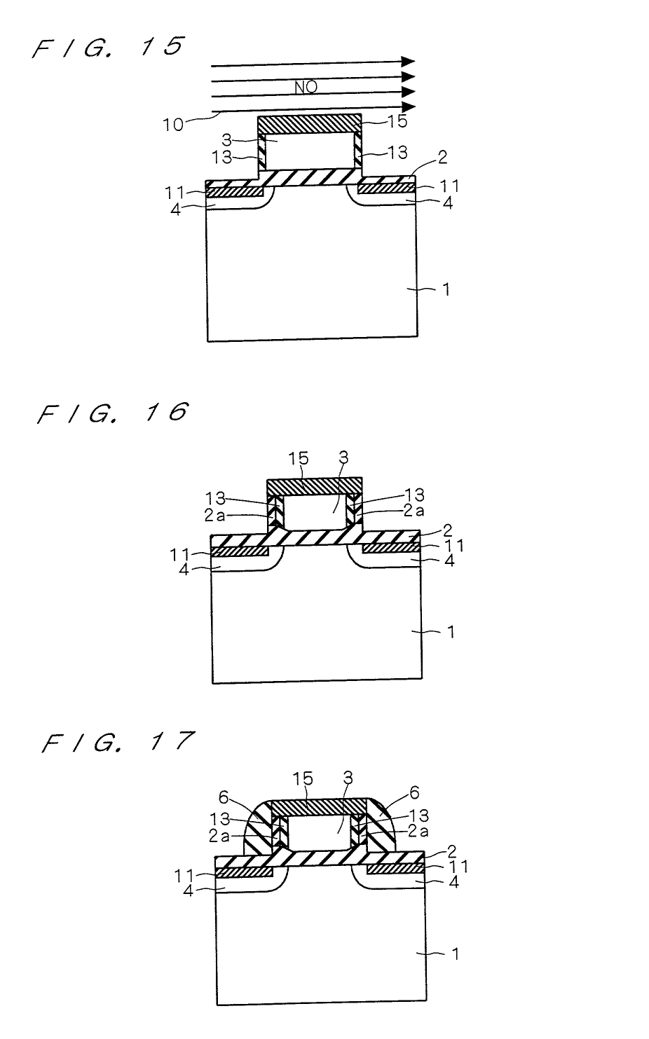

Referring to FIG. 14, by using the mask oxide film pattern 15 and polysilicon gate electrode 3 as a mask, phosphorous ion 26 is implanted to form an N⁻ region 4 that becomes part of a source/drain region. The phosphorous ion 26 is implanted, for example, at an energy of 20 keV and a dose of 1×10¹³/cm².

Referring to FIG. 15, supplying an NO gas 10, an anneal processing is performed to execute a silicon nitride film forming processing (i.e., the pretreatment of smile oxidation). For instance, supplying the NO gas 10, the anneal processing is performed at 1000° C. for 30 seconds.

Through this step, a silicon nitride film 13 is formed on the side surface of the polysilicon gate electrode 3 and a silicon nitride film 11 is formed at the interface between the out-of-gate-electrode region of the oxide film 2 and the N⁻ region 4. These silicon nitride films 11 and 13 function as an oxidation inhibiting layer.

Since nitrogen is unreactive to the oxide film 2 (SiO₂), the NO gas 10 passes through the oxide film 2 and reacts with silicon in the N⁻ region 4. Thereby, the silicon nitride film 11 is formed at the interface between the out-of-gate-electrode region of the oxide film 2 and the N⁻ region 4.

Referring to FIG. 16, by performing a smile oxidation processing in an oxygen atmosphere with a RTO (Rapid Thermal Oxidation) processing, for example, at 1100° C. for 30 seconds, there is formed the oxide film 2 of a gate bird's beak shape that the thickness of the oxide film 2 under the polysilicon gate electrode 3 is increased at the edge proximity. The oxide film 2 immediately below the polysilicon gate electrode 3 becomes a gate oxide film.

At this time, the oxidation of the surface of the silicon substrate 1 (the N⁻ region 4) and the side surface of the polysilicon gate electrode 3 in the out-of-gate-electrode region are suppressed by the presence of the silicon nitride films 11 and 13. As a result, the oxide film 2a formed on the side surface of the polysilicon gate electrode 3 (corresponding to the gate sidesurface thickness d5 in FIG. 9) and the oxide film 2 in the out-of-gate-electrode region (corresponding to the on-substrate thickness d2 in FIG. 9) are both formed so as to be thinner than the thickness under the central portion of the polysilicon gate electrode 3 (corresponding to the under-gate-electrode thickness d6 in FIG. 9).

The reason why the gate oxide film has the gate bird's beak shape is that the oxidant used in the smile oxidation processing enters the oxide film 2 via the path shown in FIG. 2 and then reaches the underside of the polysilicon gate electrode 3.

Referring to FIG. 17, a sidewall 6 is formed on the side surface of the polysilicon gate electrode 3 (including the silicon nitride film 13 and oxide film 2a). As a sidewall 6, it can be considered to use SiO₂ having a forming width of 30 nm.

Referring to FIG. 18, by using the polysilicon gate electrode 3 and sidewall 6 as a mask, arsenic ion 27 is implanted to complete an N source/drain region 5. The arsenic ion 27 is implanted, for example, at an energy of 20 keV and a dose of 1×10¹⁵/cm².

First Modification

In the fourth preferred embodiment, the silicon nitride film formation is carried out by using the NO gas 10. In place of the NO gas 10, a mixed gas of NO and O₂ may be supplied. For instance, by changing the proportion of the mixed gas (e.g., NO:O₂=1:1), it is able to change the degree of nitriding to the polysilicon gate electrode 3 or the silicon substrate 1 (the N⁻ region 4) and adjust the smile oxidation amount on the side surface of the polysilicon gate electrode 3 and on the surface of the silicon substrate 1 in the out-of-gate-electrode region.

Second Modification

Although in the fourth preferred embodiment the smile oxidation processing is carried out with the RTO processing, it may be performed by FA (Furnace Anneal) processing. There are, for example, a FA processing using dry O₂ and at 900° C for 30 minutes. Wet oxidation may be employed instead of dry oxidation.

Since the oxidation in the FA processing is performed for a sufficient time and at a lower temperature than in the RTO processing, the amount of supply becomes a greater rate controlling factor than the reaction rate. Therefore, a sufficient oxidation to the supplied oxidant is executed to provide a gate bird's beak shape deeply recessed in the polysilicon gate electrode 3.

Fifth Preferred Embodiment

FIG. 19 is a sectional view illustrating a silicon nitride film forming processing in a method of manufacturing a MOS transistor according to a fifth preferred embodiment. Referring to FIG. 19, silicon nitride films 11 and 13 are formed by using NH₃ gas 12.

For instance, supplying the NH₃ gas 12, an anneal processing is performed at 1000° C. for 30 seconds. Other steps are the same as that of the fourth preferred embodiment.

Modification

In the fifth preferred embodiment, the silicon nitride film formation is carried out by using the NH₃ gas 12. In place of the NH₃ gas 12, a mixed gas of NH₃ and O₂ may be supplied. For instance, by changing the proportion of the mixed gas, (e.g., NH₃:O₂=1:1), it is able to change the degree of nitriding to the polysilicon gate electrode 3 or the silicon substrate 1 (the N⁻ region 4) and adjust the smile oxidation amount on the side surface of the polysilicon gate electrode 3 and on the surface of the silicon substrate 1 in the out-of-gate-electrode region.

Sixth Preferred Embodiment

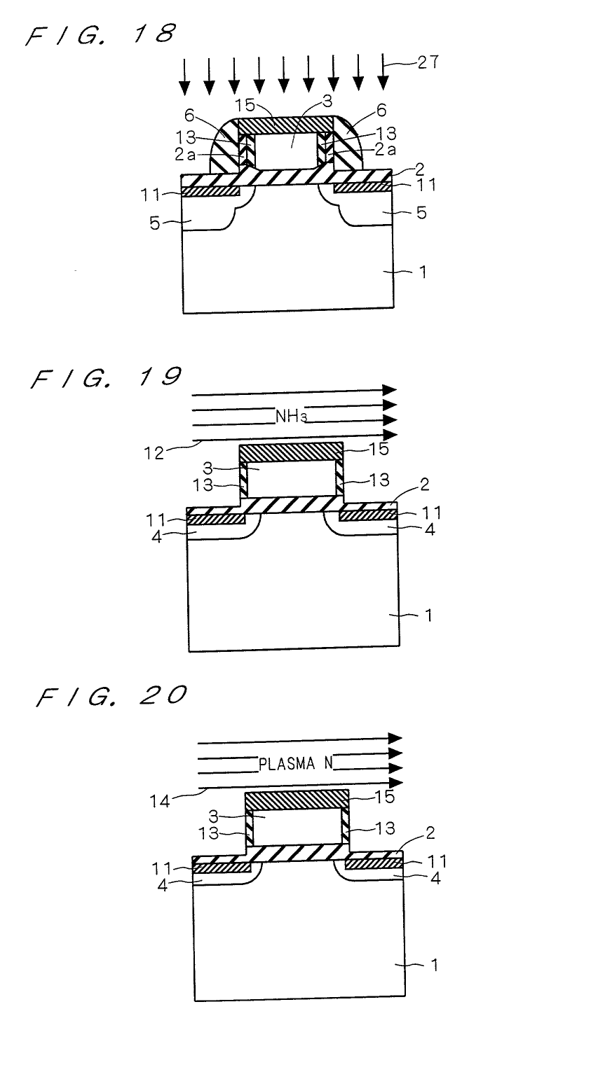

FIG. 20 is a sectional view illustrating a silicon nitride film forming processing in a method of manufacturing a MOS transistor according to a sixth preferred embodiment. Referring to FIG. 20, silicon nitride films 11 and 13 are formed by using a plasma N gas 14.

For instance, supplying the plasma N gas 14, an anneal processing is performed at 400° C. and 1.3 GHz for 30 seconds. Other steps are the same as that of the fourth preferred embodiment.

Seventh Preferred Embodiment

FIGS. 21 to 26 are sectional views illustrating in sequence the steps in a method of manufacturing a MOS transistor according to a seventh preferred embodiment. The manufacturing method of this embodiment is a method for obtaining the structure of the second preferred embodiment shown in FIG. 8.

Similarly in the fourth preferred embodiment, after an element isolation region, a well region and a channel dope layer (all of which are not shown) are formed on a silicon substrate 1, an oxide film 22, a polysilicon layer 23 and an etching mask oxide film are successively deposited. For instance, the oxide film 22, polysilicon layer 23 and etching mask oxide film are formed in a thickness of 8.0 nm, 200.0 nm and 100.0 nm, respectively.

Referring to FIG. 21, like the fourth preferred embodiment, by using a patterned resist (not shown) as a mask, the etching mask oxide film is etched to form a mask oxide film pattern 15.

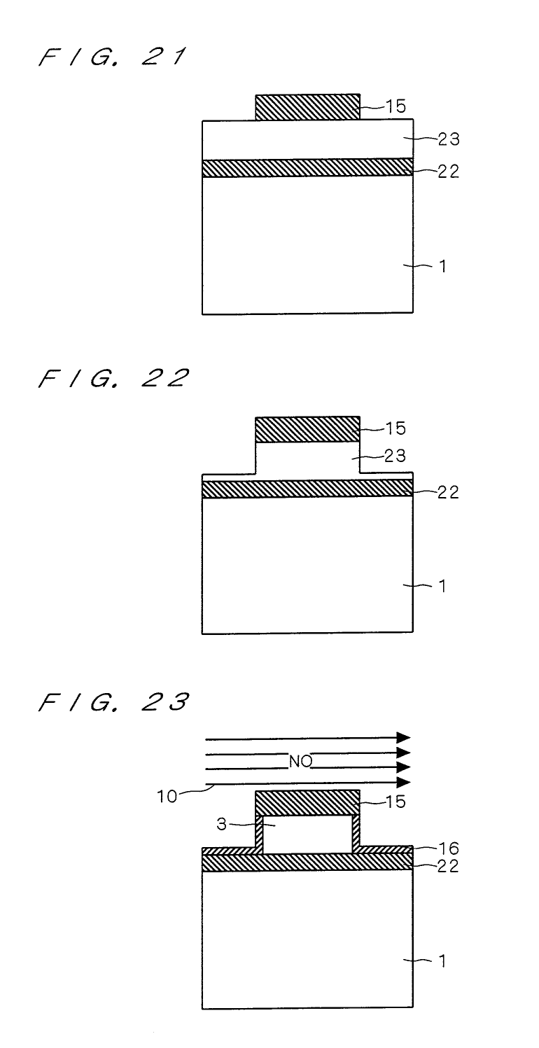

Referring to FIG. 22, by using the mask oxide film pattern 15 as a mask, the polysilicon layer 23 is etched (patterned). At this time, the region of the polysilicon layer 23 which corresponds to the out-of-gate-electrode region not covered with the mask oxide film pattern 15 is allowed to leave in a thickness of about 20.0 nm.

Referring to FIG. 23, supplying an NO gas 10, an anneal processing is performed to execute a silicon nitride film forming processing. For instance, supplying the NO gas 10, an anneal processing is performed at 1000° C. for 30 seconds. That is, the silicon nitride film forming processing using the NO gas 10 is executed in the state that the polysilicon layer 23 is exposed over the entire surface except for the mask oxide film pattern 15.

The polysilicon layer 23 not covered with the mask oxide film pattern 15 and the side surface of the polysilicon layer 23 underlying the mask oxide film pattern 15 are subjected to nitriding, thereby forming a silicon nitride film 16. The polysilicon layer 23 that is not subjected to nitriding becomes a polysilicon gate electrode 3.

Although FIG. 23 shows an example that the entire surface of the polysilicon layer 23 not covered with the mask oxide film pattern 15 is subjected to nitriding, part of the surface may be subjected to nitriding.

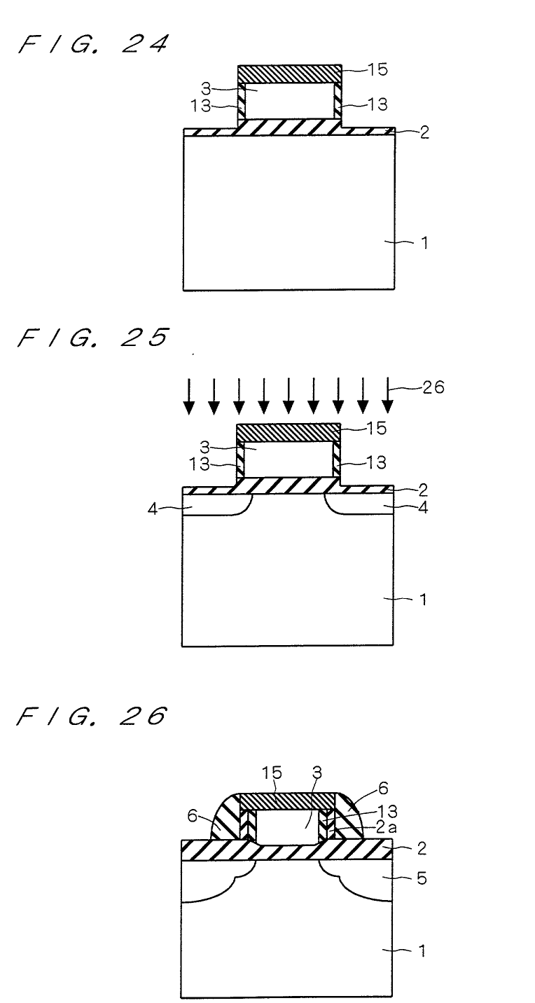

Referring to FIG. 24, by using the mask oxide film pattern 15 as a mask, the silicon nitride film 16 is etched by means of anisotropic etching. At this time, a difference in etching rate due to anisotropy is utilized to remove all the silicon nitride film 16 in the out-of-gate-electrode region, and also allow only the silicon nitride film 16 formed on the side surface of the polysilicon gate electrode 3 to remain as a silicon nitride film 13. Hereat, if part of the polysilicon layer 23 in the out-of-gate-electrode region remains without being subjected to nitriding in the silicon nitride film forming processing, the remaining polysilicon layer 23 is of course removed.

At this time, the etching is stopped at the oxide film 22. On the other hand, there is formed an oxide film 2 in which due to etching, the out-of-gate-electrode region is made thinner than the region underlying the polysilicon gate electrode 3 of the oxide film 22. Specifically, the thickness of the oxide film 2 in the out-of-gate-electrode region is reduced to about 3.0 nm.

Referring to FIG. 25, by using the mask oxide film pattern 15 and polysilicon gate electrode 3 as a mask, phosphorous ion 26 is implanted to form an N⁻ region 4 that becomes part of a source/drain region. The phosphorous ion 26 is implanted, for example, at an energy of 20 keV and a dose of 1×10¹³/cm².

Subsequently, through similar steps to the smile oxidation processing, the sidewall forming processing and the source/drain region forming processing in the fourth preferred embodiment shown in FIGS. 16 to 18, an oxide film 2 of a gate bird's beak shape, a sidewall 6 and a source/drain region 5 are formed as shown in FIG. 26.

At this time, the oxidation of the side surface of the polysilicon gate electrode 3 during the smile oxidation processing is suppressed by the presence of the silicon nitride film 13. As a result, the oxide film 2a formed on the side surface of the polysilicon gate electrode 3 (corresponding to the gate sidesurface thickness d5 in FIG. 7) has a smaller thickness than the underside of the central portion of the polysilicon gate electrode 3 (corresponding to the under-gate-electrode thickness d6 in FIG. 7).

Eighth Preferred Embodiment

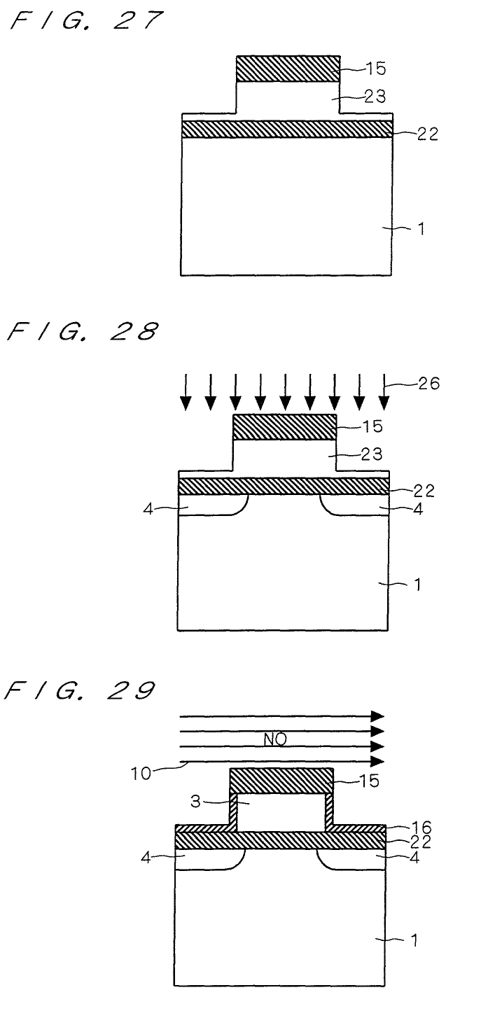

FIGS. 27 to 30 are sectional views illustrating in sequence the steps in a method of manufacturing a MOS transistor according to an eighth preferred embodiment. The manufacturing method of this embodiment is a method for obtaining the structure of the second preferred embodiment shown in FIG. 8.

Similarly in the fourth preferred embodiment, an oxide film 22, a polysilicon layer 23 and an etching mask oxide film are successively deposited on a silicon substrate 1. For instance, the oxide film 22, polysilicon layer 23 and etching mask oxide film are formed in a thickness of 8.0 nm, 200.0 nm and 100.0 nm, respectively.

Like the fourth preferred embodiment, by using a patterned resist (not shown) as a mask, the etching mask oxide film is etched to form a mask oxide film pattern 15.

Referring to FIG. 27, by using the mask oxide film pattern 15 as a mask, the polysilicon layer 23 is etched (patterned). At this time, the portion of the polysilicon layer 23 which is not covered with the mask oxide film pattern 15 is also allowed to leave in a thickness of about 20.0 nm.

Referring to FIG. 28, by using the mask oxide film pattern 15 as a mask, phosphorous ion 26 is implanted to form an N⁻ region 4. The phosphorous ion 26 is implanted, for example, at an energy of 20 keV and a dose of 1×10¹³/cm².

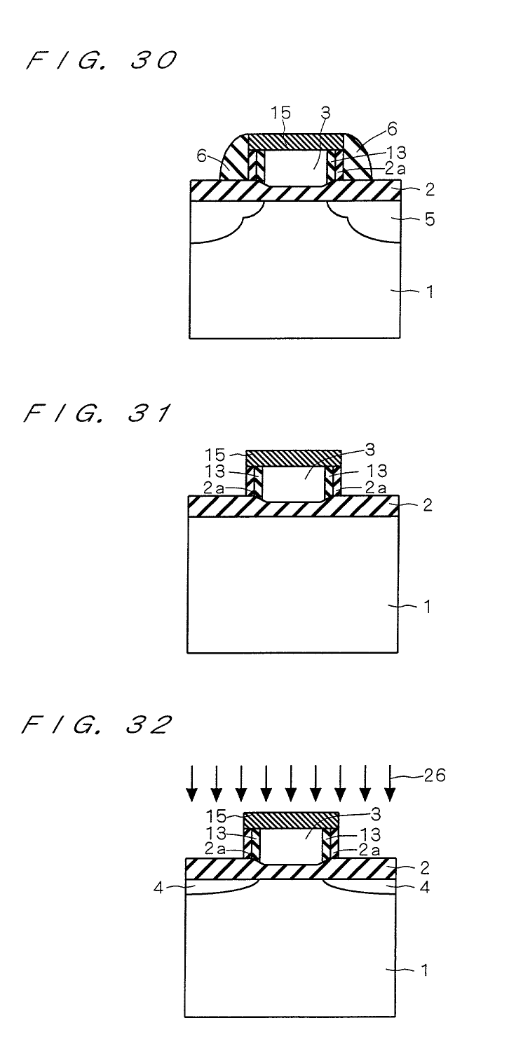

Referring to FIG. 29, like the seventh preferred embodiment, supplying an NO gas 10, an anneal processing is performed to execute the pretreatment of a smile oxidation. For instance, supplying the NO gas 10, an anneal processing is performed at 1000° C. for 30 seconds.

As a result, the polysilicon layer 23 not covered with the mask oxide film pattern 15 and the side surface of the polysilicon layer 23 underlying the mask oxide film pattern 15 are subjected to nitriding, thereby forming a silicon nitride film 16. The polysilicon layer 23 that is not subjected to nitriding becomes a polysilicon gate electrode 3.

Subsequently, the anisotropic etching processing shown in FIG. 24 in the seventh preferred embodiment, and the smile oxidation processing, sidewall forming processing and source/drain region forming processing shown in FIGS. 16 to 18 in the fourth preferred embodiment, are performed to form an oxide film 2 of a gate bird's beak shape, a sidewall 6 and a source/drain region 5, as shown in FIG. 30.

At this time, the oxidation of the side surface of the polysilicon gate electrode 3 during the smile oxidation processing is suppressed by the presence of the silicon nitride film 13. As a result, the oxide film 2a formed on the side surface of the polysilicon gate electrode 3 (corresponding to the gate sidesurface thickness d5 in FIG. 7) has a smaller thickness than the underside of the central portion of the polysilicon gate electrode 3 (corresponding to the under-gate-electrode thickness d6 in FIG. 7).

In the manufacturing method of the eighth preferred embodiment, the ion implantation processing for forming the N⁻ region 4 is carried out before the anneal processing using the NO gas 10. Therefore, in the anneal processing (thermal treatment) using the NO gas 10, an N type impurity for forming the N⁻ region 4 is diffused, and therefore, a gentle impurity profile is obtained and the field applied to the N⁻ region 4 is lessened, thus leading to a reduction in leak current.

Ninth Preferred Embodiment

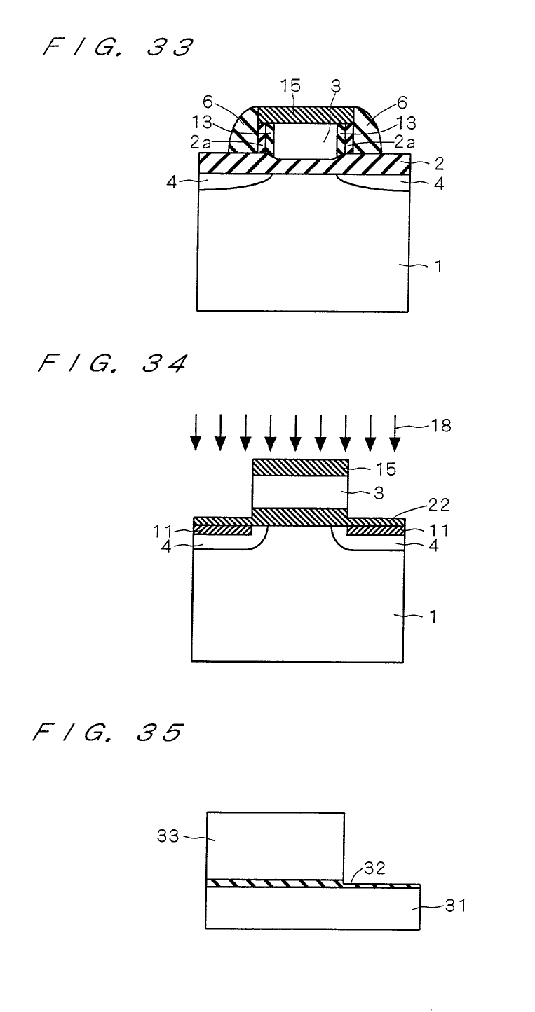

FIGS. 31 to 33 are sectional views illustrating in sequence the steps in a method of manufacturing a MOS transistor according to a ninth preferred embodiment. The manufacturing method of this embodiment is a method for obtaining the structure of the second preferred embodiment shown in FIG. 8.

After the steps similar to the seventh preferred embodiment shown in FIGS. 21 to 24, a smile oxidation processing is executed before forming an N⁻ region 4. This results in an oxide film 2 of a gate bird's beak shape as shown in FIG. 31.

At this time, the oxidation of the side surface of the polysilicon gate electrode 3 is suppressed by the presence of the silicon nitride film 13. As a result, an oxide film 2a formed on the side surface of the polysilicon gate electrode 3 has a smaller thickness than the underside of the central portion of the polysilicon gate electrode 3.

Referring to FIG. 32, by using a mask oxide film pattern 15 and the polysilicon gate electrode 3 as a mask, phosphorous ion 26 is implanted to form the N⁻ region 4.

Referring to FIG. 33, a sidewall 6 is formed on the side surface of the polysilicon gate electrode 3 (including the silicon nitride film 13 and oxide film 2a).

Subsequently, in the step similar to the source/drain region forming processing in the fourth preferred embodiment shown in FIG. 18, a source/drain region is formed to complete a MOS transistor (not shown).

Thus, in the manufacturing method of the ninth preferred embodiment, the N⁻ region 4 is formed after smile oxidation processing. Therefore, the phosphorous ion 26 can be implanted via the oxide film 2 having a larger thickness than that before smile oxidation processing. In addition, since the formation of the N⁻ region 4 is conducted after smile oxidation processing, it is free of the influence of thermal treatment during the smile oxidation processing.

Thereby, the N⁻ region 4 of which forming depth is relatively shallow can be formed and a shallow junction structure can be realized, thus permitting the device miniaturization.

Tenth Preferred Embodiment

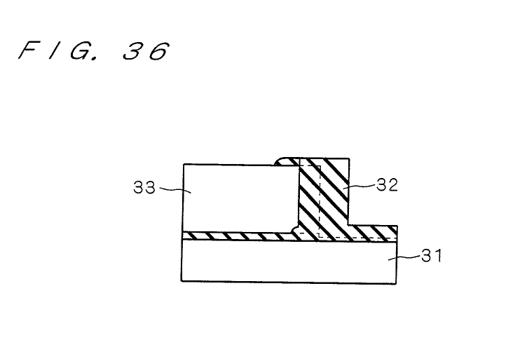

FIG. 34 is a sectional view illustrating a silicon nitride film forming step in a method of manufacturing a MOS transistor according to a tenth preferred embodiment. The manufacturing method of this embodiment is a method for obtaining the structure of the first preferred embodiment shown in FIG. 6.

Referring to FIG. 34, after the steps similar to the fourth preferred embodiment shown in FIGS. 12 to 14, nitrogen ion 18 is implanted from above by using a nitrogen implantation method, to form a silicon nitride film 11 at the interface between the out-of-gate-electrode region of an oxide film 2 and a silicon substrate 1. Note that no silicon nitride film is formed on the side surface of a polysilicon gate electrode 3.

In order that only the silicon nitride film 11 is selectively formed, the ion entry angle when implanting the nitrogen ion 18 is preferably orthogonal to the silicon substrate 1. It is more preferable to conduct the implantation with parallel beams suppressing variations in the entry angle. For instance, the implantation is carried out at an energy such that the nitrogen ion 18 reaches the surface of the silicon substrate 1, and at a dose of 1×10¹⁵/cm². Alternatively, nitrogen N₂ may be introduced instead of the nitrogen ion 18.

Subsequently, through similar steps to the smile oxidation processing, sidewall forming processing and source/drain region forming processing in the fourth preferred embodiment shown in FIGS. 16 to 18, an oxide film 2 of a gate bird's beak shape, a sidewall 6 and a source/drain region 5 are formed.

At this time, the oxidation of the surface of the silicon substrate 1 in the out-of-gate-electrode region (i.e., the N⁻ region 4) is suppressed by the presence of the silicon nitride film 11. As a result, an oxide film 2 in the out-of-gate-electrode region (corresponding to the on-substrate thickness d2 in FIG. 5) is made thinner than the underside of the central portion of the polysilicon gate electrode 3 (corresponding to the under-gate-electrode thickness d6 in FIG. 5).

Others

In the tenth preferred embodiment, the polysilicon gate electrode is used as a gate electrode. Even when the gate electrode is formed by a metal layer, by forming a silicon nitride film 13 on the side surface, the same oxidation inhibiting function can be offered by the silicon nitride film 13. Accordingly, even when a gate electrode made of metal is used instead of the polysilicon gate electrode 3, the same effect is obtained without using the selective oxidation technique. This enables to lower the manufacturing cost.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device including a MOS transistor having:
a semiconductor substrate;
an oxide film disposed on said semiconductor substrate; and
a gate electrode selectively disposed on said oxide film,
said oxide film being disposed on an underside and a side surface of said gate electrode, and being disposed on said semiconductor substrate in an out-of-gate-electrode region corresponding to a region other than the underside and the side surface of said gate electrode,
said oxide film underling said gate electrode being made thicker in thickness under the edge proximity than under the central portion of said gate electrode, and
said oxide film to be disposed on said out-of-gate-electrode region being made thinner in thickness than said oxide film to be disposed on the side surface of said gate electrode.

2. The semiconductor device according to claim 1, wherein
said oxide film to be disposed on said out-of-gate-electrode region is made thinner in thickness than said oxide film under the central portion of said gate electrode.

3. The semiconductor device according to claim 1, further comprising:
an oxidation inhibiting layer composed of an antioxidant disposed between said semiconductor substrate and said oxide film in said out-of-gate-electrode region.

4. A semiconductor device including a MOS transistor having:
a semiconductor substrate;
an oxide film disposed on said semiconductor substrate; and
a gate electrode selectively disposed on said oxide film,
said oxide film being disposed on an underside and a side surface of said gate electrode,
said oxide film underling said gate electrode being made thicker in thickness under the edge proximity than under the central portion of said gate electrode, and
said oxide film to be disposed on the side surface of said gate electrode being made thinner than said oxide film to be disposed under the central portion of said gate electrode.

5. The semiconductor device according to claim 4 further comprising:
an oxidation inhibiting layer composed of an antioxidant disposed between the side surface of said gate electrode and said oxide film.

6. The semiconductor device according to claim 4, wherein
said oxide film is also disposed on said semiconductor substrate in an out-of-gate-electrode region corresponding to a region other than the underside and side surface of said gate electrode, and
said oxide film in said out-of-gate-electrode region is made thinner in thickness than said oxide film to be disposed under the central portion of said gate electrode.

7. The semiconductor device according to claim 6 further comprising:
a first oxidation inhibiting layer composed of an antioxidant disposed between the side surface of said gate electrode and said oxide film; and
a second oxidation inhibiting layer composed of an antioxidant disposed between said semiconductor substrate and said oxide film in said out-of-gate-electrode region.

8. A method of manufacturing a semiconductor device comprising the steps of:
(a) successively depositing an oxide film and a conductive layer on a semiconductor substrate;
(b) patterning said conductive layer to form a gate electrode, by performing the step (b), said oxide film being made thinner in thickness in an out-of-gate electrode region where said gate electrode is not formed;
(c) forming an oxidation inhibiting layer composed of an antioxidant between said oxide film and said semiconductor substrate in said out-of-gate-electrode region;
(d) performing an oxidation processing over the entire surface of said semiconductor substrate after the step (c); and
(e) introducing impurity of a predetermined conductivity by using said gate electrode as a mask, to form a source/drain region in the surface of said semiconductor substrate, wherein
a MOS transistor is made up of said gate electrode, said oxide film underlying said gate electrode and said source/drain region,
by performing the step (d), said oxide film underlying said gate electrode is formed on the side surface of said gate electrode and is made thicker in thickness under the edge proximity than the under the central portion of said gate electrode, and
said oxide film in said out-of-gate-electrode region is made thinner in thickness than said oxide film to be formed on the side surface of said gate electrode.

9. The method according to claim 8, wherein
by performing the step (d), said oxide film in said out-of-gate-electrode region is made thinner in thickness than said oxide film underlying the central portion of said gate electrode.

10. The method according to claim 8, wherein
the step (c) includes the step of implanting from above gas having an oxidation inhibiting function and having higher reactivity with said semiconductor substrate than said oxide film by using said gate electrode as a mask, to form said oxidation inhibiting layer.

11. A method of manufacturing a semiconductor device comprising the steps of:
(a) successively depositing an oxide film and a conductive layer on a semiconductor substrate;
(b) patterning said conductive layer to form a gate electrode;
(c) forming a first oxidation inhibiting layer composed of an antioxidant on the side surface of said gate electrode;
(d) performing an oxidation processing over the entire surface of said semiconductor substrate after step (c); and
(e) introducing impurity of a predetermined conductivity by using said gate electrode as a mask, to form a source/drain region in the surface of said semiconductor substrate, wherein
a MOS transistor is made up of said gate electrode, said oxide film underlying said gate electrode and said source/drain region,
by performing the step (d), said oxide film underlying said gate electrode is formed on the side surface of said gate electrode and is made thicker in thickness under the edge proximity than under the central portion of said gate electrode, and
said oxide film to be formed on the side surface of said gate electrode is made thinner in thickness than said oxide film underlying the central portion of said gate electrode.

12. The method according to claim 11 wherein
the step (b) includes the step of allowing part of said conductive layer to remain in an out-of-gate-electrode region corresponding to the area except for the region for forming said gate electrode, and
the step (c) further includes the step of removing said conductive layer and said first oxidation inhibiting layer in said out-of-gate-electrode region after forming said first oxidation inhibiting layer.

13. The method according to claim 12, wherein
the step (c) includes a thermal treatment, and
the step (e) includes the steps of:
(e-1) introducing impurity of said predetermined conductivity at a first impurity concentration; and
(e-2) introducing impurity of said predetermined conductivity at a second impurity concentration higher than said first impurity concentration, and
the step (e-1) is performed before the step (c).

14. The method according to claim 12, wherein
the step (e) includes the steps of:
(e-1) introducing impurity of said predetermined conductivity at a first impurity concentration; and
(e-2) introducing impurity of said predetermined conductivity at a second impurity concentration higher than said first impurity concentration, and
the step (e-1) is performed after the step (d).

15. The method according to claim 11, wherein
the step (c) includes the step of supplying gas having an oxidation inhibiting function and reacting with said conductive layer including said gate electrode.

16. The method according to claim 11, wherein
by performing the step (b), said oxide film is made thinner in thickness in an out-of-gate-electrode region where said gate electrode is not formed,
the step (c) includes the step of forming a second oxidation inhibiting layer composed of an antioxidant between said oxide and said semiconductor substrate film in said out-of-gate-electrode region, and
by performing the step (d), said oxide film in said out-of-gate-electrode region is made thinner in thickness than said oxide film to be formed under the central portion of said gate electrode.

17. The method according to claim 16, wherein
the step (c) includes the step of supplying gas having an oxidation inhibiting function, reacting with said gate electrode and having higher reactivity with said semiconductor substrate than said oxide film.
